(19) United States
(12) Patent Application Publication
(10) Pub. No.: US 2009/0050921 A1
(43) Pub. Date: Feb. 26, 2009

(54) Light Emitting Diode Array

(75) Inventors: Serge J. Bierhuizen, Santa Rosa, CA (US); Gerard Harbers, Sunnyvale, CA (US)

Correspondence Address: PATENT LAW GROUP LLP, 2635 NORTH FIRST STREET, SUITE 223, SAN JOSE, CA, 95134, US

(73) Assignee: Philips Lumileds Lighting Company LLC, San Jose, CA (US)

(21) Appl. No.: 11/844,279

(22) Filed: Aug. 23, 2007

(51) Int. Cl. H01L 33/00

(52) U.S. Cl. 257/99; 257/E33.005

(57) ABSTRACT

A one-dimensional array of light emitting diodes (LEDs) is configured to place the LEDs in close proximity to each other, e.g., 150 μm or less and to place at least one side of the LEDs in close proximity to the edge of the substrate, e.g., 150 μm or less. With the LEDs close to the edge of the substrate, multiple one-dimensional arrays may be joined together, side by side, to form a two-dimensional array with the LEDs from adjacent one-dimensional arrays positioned close together. By minimizing the gaps between the LEDs on the same one-dimensional arrays and adjacent one-dimensional arrays, the luminance of the device is improved making the device suitable for high radiance applications. Moreover, using a number of one-dimensional arrays to form a larger two-dimensional array increases yield relative to conventional monolithic two-dimensional arrays.

### FIELD OF THE INVENTION

The invention relates to an array of light emitting devices and in particular to one-dimensional arrays of light emitting diodes that may be combined to form two-dimensional arrays of different sizes.

### BACKGROUND

Semiconductor light emitting device, such as light emitting diodes (LEDs), are efficient light sources. For many applications, particularly high brightness applications with etendues greater than 3 mm²sr, it is often desirable to place multiple LEDs in an array. As luminance is a function of the proximity of the LEDs to one another, it is desirable to place the LEDs close together in such arrays. To form arrays conventionally, LEDs are individually mounted on a monolithic substrate either directly or using an intervening submount. Accurately bonding a large number of LEDs to a single substrate, however, is difficult has a relatively low yield. For example, with a 10% failure rate per LED, mounting 15 LEDs in a 3×5 two-dimensional array results in a yield of approximately 21% (90%\hat{0}15).

It is, thus, desirable to produce an improved array of LEDs so that the LEDs can be placed in close proximity to each and increase the overall yield.

### SUMMARY

In accordance with one embodiment, a one-dimensional array of light emitting diodes (LEDs) is configured to place the LEDs in close proximity to each other, e.g., 150 μm or less and to place at least one side of the LEDs in close proximity to the edge of the substrate of the array, e.g., 150 μm or less. With the LEDs close to the edges of the substrate, multiple one-dimensional arrays may be joined together, side by side, to form a two-dimensional array with the LEDs from adjacent one-dimensional arrays positioned close together. By minimizing the gaps between the LEDs on the same one-dimensional arrays and adjacent one-dimensional arrays, the luminance of the device is improved making the device suitable for high radiance applications. Moreover, using a number of one-dimensional arrays to form a larger two-dimensional array increases yield relative to conventional monolithic two-dimensional arrays.

### BRIEF DESCRIPTION OF THE DRAWINGS

FIG. 1 illustrates a top plan view of a one-dimensional light emitting diode (LED) array.

FIG. 2 illustrates a plurality of one-dimensional arrays combined side by side to form a two-dimensional array.

FIG. 3 illustrates a top plan view of a heat sink to which the two-dimensional array shown in FIG. 2 may be mounted.

FIG. 4 is a side view of a two-dimensional array mounted on a substrate with a cooling interface coupled to the overlying LEDs.

FIG. 5 is a top view of the two-dimensional array shown in FIG. 4.

FIG. 6 illustrates a top plan view of the substrate used for the one-dimensional array of FIG. 1.

FIG. 7 illustrates a closer view of a portion of the one-dimensional array of FIGS. 1 and 6.

FIG. 8 illustrates a top view of a plurality of substrates being produced on a single tile before mounting the LEDs and dicing into individual one-dimensional arrays.

FIG. 9 illustrates a top plan view of another embodiment of a one-dimensional array in which the contact leads are located on the same side of the top surface of the substrate.

FIG. 10 is a cross sectional view of the one-dimensional array along lines A-A in FIG. 9.

FIG. 11 illustrates an example of a two-dimensional array produced using a number of one-dimensional arrays.

FIG. 12 illustrates a 2×3 two-dimensional array formed form two 1×3 one-dimensional arrays coupled in series.

FIG. 13 illustrates another embodiment of a one-dimensional array in which the LEDs are coupled together in parallel.

### DETAILED DESCRIPTION

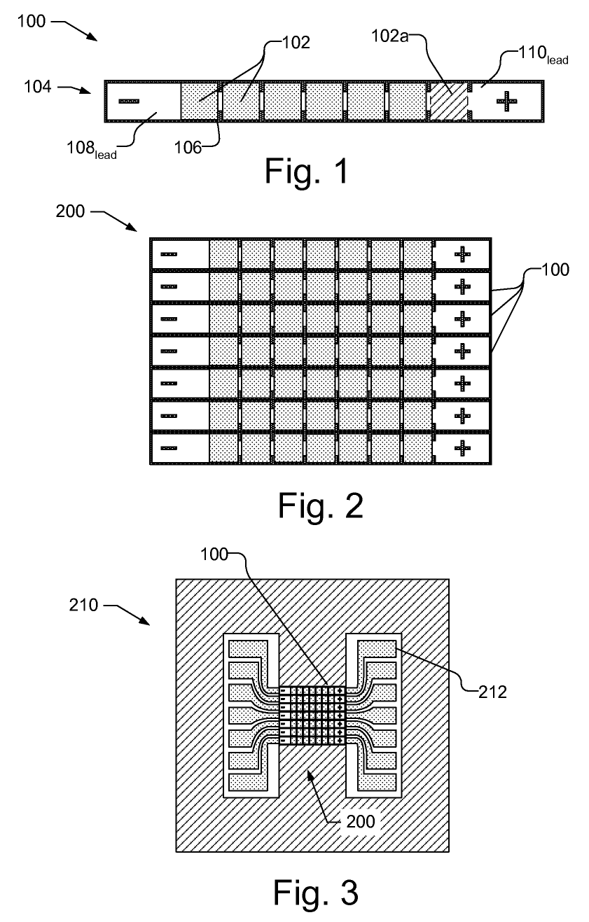

FIG. 1 illustrates a top plan view of a one-dimensional light emitting diode (LED) array 100 that includes a substrate 104 populated with a plurality of light emitting diodes (LEDs) 102. The substrate 104 includes an insulating base 106 with a top surface that is covered with a patterned conductive layer to form the N contact lead 108_{lead} and the P contact lead 110_{lead} for the LEDs 102, as well as the N contacts 108 and P contacts 110, which are hidden from view by the LEDs 102 in FIG. 1 but are shown in FIG. 6. The LEDs 102 are coupled together in series with the N contact lead 108_{lead} and P contact lead 110_{lead} on opposite sides of the substrate 104.

The one-dimensional array 100 is illustrated in FIG. 1 as being capable of holding up to seven LEDs 102. However, if desired the array 100 may be configured to hold more or fewer LEDs 102. The one-dimensional array 100 may be generally referred to as 1×N array, where N≧2. Arrays, similar to array 100 shown in FIG. 1 but having different numbers N of LEDs may be produced in light of the present disclosure. Moreover, if desired, one or more of the LED mounting locations on the one-dimensional array 100 may be unpopulated and short-circuited, which is illustrated in FIG. 1 by the cross-hatching in LED 102a. As illustrated in FIG. 2, a plurality of one-dimensional 1×N arrays 100 may be combined, i.e., mounted adjacent to one another, to form a two-dimensional M×N array 200, where M≧2. The one-dimensional arrays 100 used to produce the two-dimensional array 200 may be populated with the same number of LEDs 102 or, alternatively, one or more of the one-dimensional arrays 100 may have a different number of LEDs 102 to produce the desired array configuration.

An advantage of using many individual one-dimensional arrays 100 to form a two-dimensional array is that the overall yield is improved. For example, a conventional monolithic two-dimensional array of 15 LEDs, e.g., 3×5 array, may have a yield of 21% (90%\hat{0}15), while using five one-dimensional 1×3 arrays could result in a yield of 69% (90%\hat{0}3*99%\hat{0}5), assuming a yield of 99% of mounted and electrically connecting the five strips closely together.

FIG. 3 illustrates a top plan view of a heat sink 210 to which the M×N array 200 may be mounted. The heat sink 210 may be formed of thermally conductive material such as aluminum or copper or alloys thereof. The heat sink 210 includes electrically isolated leads 212, which are electrically coupled to the N and P contact leads 108, 110 of individual 1×N arrays 100, e.g., by wire bonding or by solder-reflow on the bottom surface substrate 104, where through-vias (not shown) in the substrate 104 provide electrical contact to the N and P contacts 108, 110 on the top surface. The substrates 104 of the one-dimensional arrays 100 may be soldered to the heat sink 210 to provide good thermal contact and low thermal resistance from the LEDs 102 through the substrate of the one-dimensional arrays 100 to the heat sink 210.

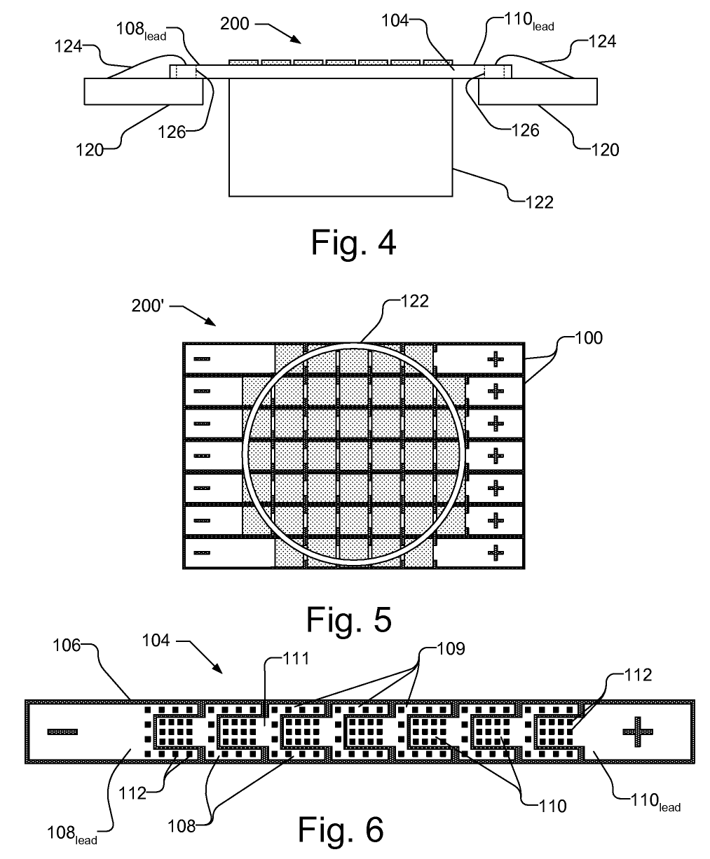

FIG. 4 is a side view of an array 200′, which is similar to the array 200 shown in FIG. 2, and that is coupled to a direct bond copper (DBC) substrate 120, which has a hole under the location of the LEDs to provide thermal contact with a heat pipe 122 or other appropriate cooling interface. As can be seen in FIG. 4, wire bonds 124 provide electrical contact between the DBC substrate 120 and the N and P contact leads 108 and 110. Alternatively, electrical contact between the DBC substrate 120 and the N and P contact leads 108 and 110 is achieved with through-vias 126 in the substrate 104, illustrated with broken lines.

FIG. 5 is a top view of array 200′, shown in FIG. 4, with a circle illustrating the location of the heat pipe 122. As can be seen in FIG. 5, array 200′ may include one or more one-dimensional arrays 100 with varying numbers of LEDs 102, which may be advantageous to optimize the thermal interface or simply to produce a desired array area. The circle may alternatively represent the shape of an optical system, such as a round spot-lamp, where using a varying number of LEDs per strip assist in achieving the ideal shape of the optical system.

FIG. 6 illustrates a top plan view of the substrate 104 for the one-dimensional array 100. The substrate 104 includes a base 106 that may be, e.g., ceramic, Al₂O₃, AlN, alumina, or silicon nitride. The base 106 is covered with patterned conductor regions 109 to form electrically isolated N-contacts 108 and the P-contacts 110 for the LEDs in a serial arrangement with a conductive bridge 111 between them. The conductor regions 109 maybe conventionally deposited and patterned lithographically, e.g., from Au or Cu or suitable metal or metal alloy, and may have a thickness of, e.g., 2 μm. Over the N and P contacts 108 and 110 at the LED sites are plated bumps 112, which provide electrical contact with the LEDs 102 when they are mounted on the substrate 104. The plated bumps 112 may be, e.g., Au plating that is 15-30 μm thick with, e.g., 50% of area coverage.

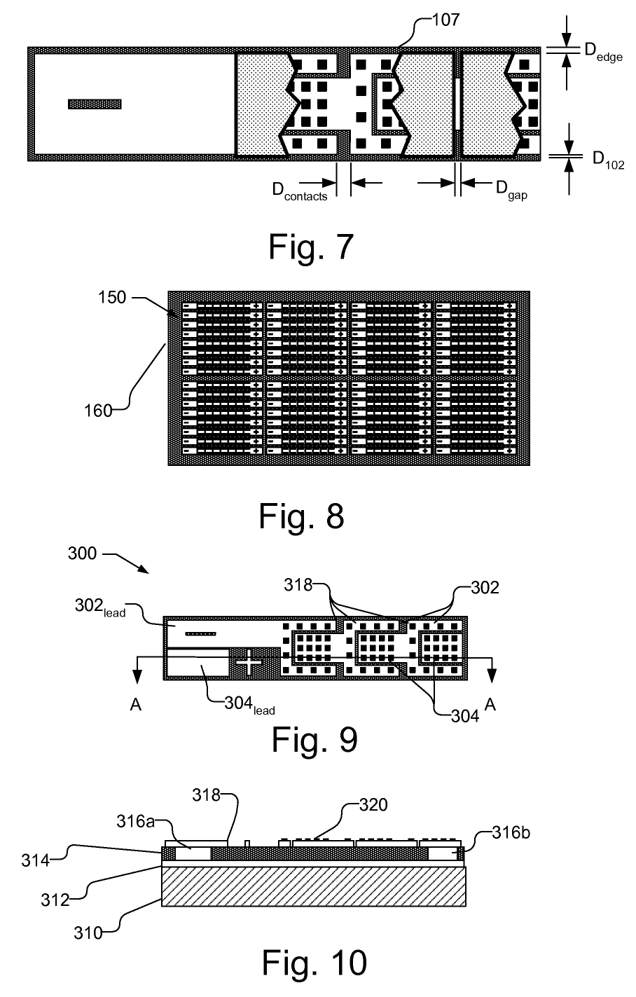

FIG. 7 illustrates a closer view of a portion of the array 100, with portions of the LEDs 102 cut away. The array 100 is configured so that the LEDs 102 may be mounted close together to improve luminance of the device, making the array 100 suitable for high radiance devices, such as rear projection systems, and high lumens/Watt systems, such as pocket projectors. In general, luminance L=Flux/(Area*pi) and the Area for an M×N array is Area=(M*Width_of_LED+(M−1)*Gap_Width)*(N*Length_of_LED+(N−1)*Gap_Length). Thus, the larger the Gap_Length or Gap_Width, the greater the Area and the lower the luminance L, assuming the same total flux from the LEDs.

The N-contact 108 and P-contact 110 are formed so that the gap between the LEDs 102, distance D_{gap}, when mounted on the substrate 104 is 150 μm or less, and is preferably 100 μm or less, such as 75 μm or 50 μm. To minimize the distance D_{gap}, the N contacts 110 for two adjacent LED sites are configured to be close together, e.g., a distance D_{contacts}. The LED die placement, which have a tolerance of, e.g., ±15 μm, must be accounted for in determining the minimum distance D_{contacts}, and, thus, the distance D_{gap}. If the distance D_{contacts} is too small, the LED dies can short out or touch each other during LED die placement. The manufacturing tolerances of the placement of the plated bumps 112 also add to the tolerance, e.g., ±15 μm. By minimizing the gap between the LEDs 102 on the substrate 104, the luminance of the array 100 is increased.

Additionally, the substrate 104 is configured so that the distance D_{edge} between the edge of the LEDs 102 and at least one edge 107 of the base 106 is minimized, e.g., 150 μm or less, and is preferably 100 μm or less, such as 75 μm or 50 μm. By minimizing the distance D_{edge}, the distance between LEDs 102 from two adjacent one-dimensional arrays 100 will be no more than 300 μm. To minimize the distance D_{edge}, the N contacts 108 are configured so that they extend minimally or not at all beyond the edges of the LEDs 102, i.e., the distance D₁₀₂ is less than 50 μm, and is preferably 25 μm or less such as 0.0 μm, except for the bridge 111 that makes electrical contact to the P contact 110 under a neighboring LED site or to the N contact lead 108_{lead}. By configuring the metal N contacts 108 so that they lie completely underneath the LEDs 102, the base 106 of the substrate 104 can be sawn very close to the edges of the LEDs 102 without contacting the metal contact material, which would interfere with the sawing of the base 106, as well as risk shorts with neighboring arrays when closely placed together. It should be understood that the present embodiment is based on an LED flip-chip configuration wit the N contacts on the parameter of the LED die. With other configurations, such as the P contacts on the parameter of the LED die, or the N contact and P contacts opposite sides of the LED die, the configuration of N contacts 108 and P contacts 110 could be altered appropriately in light of the present disclosure.

In manufacturing, a plurality of substrates 104 may be produced at the same time from a single large tile. FIG. 8, by way of example, illustrates a top view of a plurality of substrates 104 being produced on a single tile 160 before mounting the LEDs 102 and dicing into individual arrays 100. After substrates 104 are formed, with the contacts regions 109 and plated bumps 112 (FIG. 6) formed, the LEDs 102 are populated on the tile 160. The LEDs 102 may be any desired flip-chip design, and is preferably a III-nitride device, which are conventionally epitaxially grown on sapphire, silicon carbide, or III-nitride substrates. Once the LEDs 102 are mounted, a conventional epoxy underfill process may be performed followed by the removal of the growth substrate, e.g., using a laser lift off or other appropriate process. The remaining top surface of the LEDs 102 are then roughened using, e.g., a photoelectrochemical (PEC) or other appropriate process to improve light extraction. The individual one-dimensional arrays 100 can then be diced, e.g., using a sawing process, tested, and mounted and electrically connected in multiple 1×N units on a heat sink.

In addition, the designs of the substrate 104 eliminates the need for wire bonds and avoids placing components that are higher than the LEDs, such as transient voltage suppressor (TVS) within a close parameter from the array of LEDs 102. Consequently, optical components such as lenses may be placed close, e.g., 100 μm or less to top surface of the LEDs.

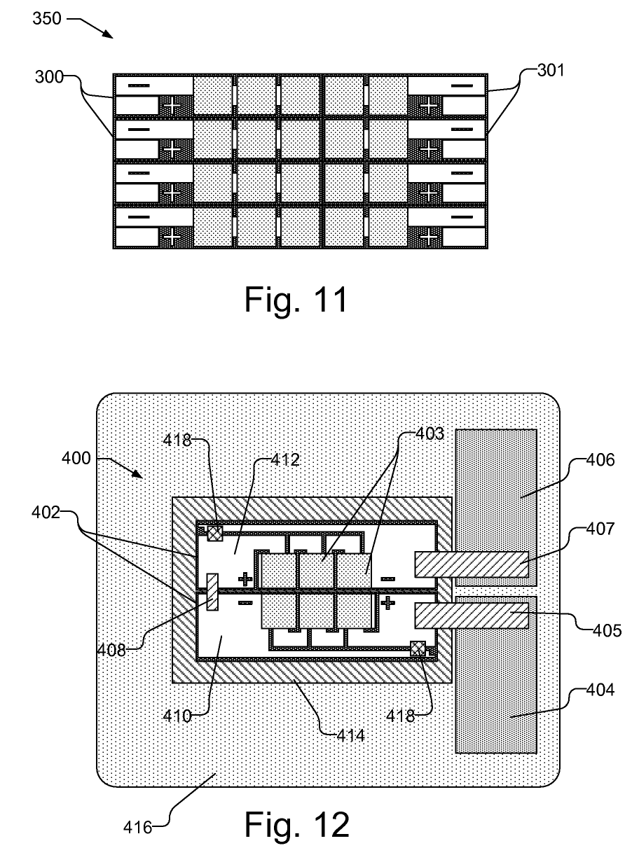

FIG. 9 illustrates a top plan view of another embodiment of a one-dimensional (1×3) array 300 in which the N contact lead 302_{lead} and P contact lead 304_{lead} are located on the same side of the substrate 306. FIG. 10 is a cross sectional view of the one-dimensional array 300 along lines A-A in FIG. 9. It should be understood that the size of array 300 may be varied from what is illustrated, e.g., the array may be 1×2, 1×4 or larger. FIG. 11 illustrates an example of a two-dimensional 4×5 array 350 produced using four one-dimensional 1×3 arrays 300 and four one-dimensional 1×2 arrays 301. Of course, different sized two-dimensional arrays may be produced using larger or smaller one-dimensional arrays as well using fewer or additional one-dimensional arrays.

As illustrated in FIG. 10, the substrate 306 is formed from a base 310, e.g., of silicon, with a conductive bottom layer 312, e.g., of Au or Cu, that is 2 μm thick. An insulating layer 314 overlies the bottom layer 312. The insulating layer 314 may be, e.g., a 1.5 μm thick layer of silicon oxide or other appropriate material. As can be seen in FIG. 10, two through vias 316a, 316b, of Au or other appropriate material, are present in the insulating layer 314. Through via 316a is located under the P contact lead 304, while the through via 316b is located under the P contact area for the farthest LED in the array. Over the insulating layer 314 is the patterned conductor regions 318, which form the contact leads 302_{lead} and 304_{lead} and the N-contacts 302 and the P-contacts 304 for the LEDs. Over the conductor regions 318 are the plated bumps 320, which provide electrical contact with the LEDs.

FIG. 12 illustrates a top plan view of two 1×3 one-dimensional arrays 402 of LEDs 403 mounted together to form a 2×3 two-dimensional array 400. The one-dimensional arrays 402 may be formed in a manner similar to array 100 described in FIG. 1, e.g., with patterned metal contacts overlying an insulating base. The two one-dimensional arrays 402 are coupled in series between the positive lead 404 and the negative lead 406, via conductive ribbons 405 and 407, with a jumper 408 coupling the N contact 410 of one array to the positive contact 412 of the other array. The arrays 402 are mounted on a slug 414 for heat sinking and is surrounded by molded body 416 of plastic or other appropriate material. The one-dimensional arrays 402 further include TVS diodes 418. As can seen in FIG. 12, the arrays 402 are configures so that only one side of the LEDs 403 are close to the edge of the substrate. Moreover, components that are higher than the LEDs 403, such as the jumper 408, ribbons 405 and 407, and the TVS diodes 4018 are positioned outside a close parameter to the LEDs, e.g., greater than 0.5 mm, and more specifically greater than 1 mm or 2 mm. Consequently, optical components such as lenses may be placed close, e.g., 100 μm or less to the array of LEDs without interference from the jumper 408, ribbons 405 and 407, and the TVS diodes 4018.

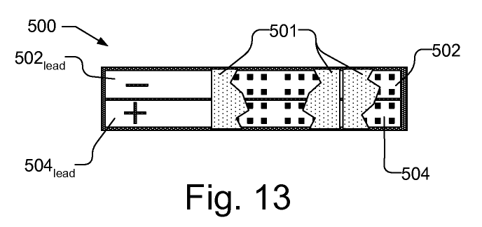

FIG. 13 illustrates another embodiment of a one-dimensional array 500 in which the LEDs 501 (only a portion of the LEDs is illustrated) are coupled to the N contact lead 502_{lead} and the P contact lead 504_{lead} in parallel via N contacts 502 and P contacts 504. Thus, the N contacts 502 are coupled together and the P contacts 504 are coupled together.

Although the present invention is illustrated in connection with specific embodiments for instructional purposes, the present invention is not limited thereto. Various adaptations and modifications may be made without departing from the scope of the invention. Therefore, the spirit and scope of the appended claims should not be limited to the foregoing description.

What is claimed is:

1. An apparatus comprising:
a one-dimensional array of light emitting diodes, the one-dimensional array comprising:
a substrate having a base and a plurality of electrically conductive contact regions disposed on the base;
a plurality of light emitting diodes, each light emitting diode having a flip-chip configuration and mounted on one of the plurality of conductive contact regions, wherein each light emitting diode is separated by 150 μm or less from another light emitting diode and wherein each light emitting diode has an edge that is separated by 150 μm or less from a side of the base.

2. The apparatus of claim 1, wherein the plurality of light emitting diodes are electrically coupled together in series through the contact regions.

3. The apparatus of claim 1, further comprising a positive contact lead and a negative contact lead on opposite sides of a top surface of the base.

4. The apparatus of claim 1, further comprising a positive contact lead and a negative contact lead on a same side of a top surface of the base.

5. The apparatus of claim 4, wherein the substrate further comprises a conductive layer disposed over the base, an insulating layer disposed over the conductive layer, and the plurality of electrically conductive contact regions disposed over the insulating layer; the substrate further comprising a first through via in the insulating layer under one of the positive contact lead and the negative contact lead, and a second through via in the insulating layer under a contact region under a light emitting diode that is on the opposite side of the top surface of the base with respect to the positive contact lead.

6. The apparatus of claim 1, wherein the contact regions are configured so that a positive contact area under one light emitting diode is electrically coupled to a negative contact area under an adjacent light emitting diode.

7. The apparatus of claim 1, wherein the plurality of light emitting diodes are electrically coupled together in parallel through the contact regions so that a positive contact area under one light emitting diode is electrically coupled to a positive contact area under an adjacent light emitting diode.

8. The apparatus of claim 1, wherein each contact region has a side that does not extend beyond 50 μm from the edge of an overlying light emitting diode.

9. The apparatus of claim 1, wherein each light emitting diode is separated by 100 μm or less from another light emitting diode and wherein each light emitting diode has an edge that is separated by 100 μm or less from a side of the base.

10. The apparatus of claim 1, further comprising a plurality of one-dimensional arrays of light emitting diodes configured to form a two-dimensional array of light emitting diodes, wherein the light emitting diodes on each one-dimensional array are less than 300 μm from a light emitting diode on an adjacent one-dimensional array.

11. The apparatus of claim 1, wherein at least one of the one-dimensional arrays has a different number of light emitting diodes than the remaining one-dimensional arrays.

12. The apparatus of claim 1, wherein the light emitting diodes have a height and wherein there is no component with a height greater than the light emitting diode height that is closer than 2 mm from one of the light emitting diodes.

13. A two-dimensional array of light emitting diodes comprising:
a plurality of one-dimensional arrays of light emitting diodes, each one-dimensional array of light emitting diodes comprising a plurality of flip-chip light emitting diodes mounted on a substrate, wherein each light emitting diode on a substrate is separated by 150 μm or less from another light emitting diode on the same substrate and wherein each light emitting diode is separated by 300 μm or less from a light emitting diode on an adjacent one-dimensional array.

14. The two-dimensional array of light emitting diodes of claim 13, wherein the two-dimensional array is an M×N array, where M≧2 and N≧2, wherein there are M one-dimensional arrays and each of the M one-dimensional arrays is a 1×N array.

15. The two-dimensional array of light emitting diodes of claim 13, wherein at least one of the one-dimensional arrays has a different number of light emitting diodes than the remaining one-dimensional arrays.

16. The two-dimensional array of light emitting diodes of claim 13, wherein each one-dimensional array further comprises conductive contact regions on the substrate that underlie the light emitting diodes, each contact region has a side that does not extend beyond 50 μm from the edge of an overlying light emitting diode.

17. The two-dimensional array of light emitting diodes of claim 13, wherein the plurality of flip chip light emitting diodes on each one-dimensional array are electrically coupled together in series.

18. The two-dimensional array of light emitting diodes of claim 13, wherein the plurality of flip chip light emitting diodes on each one-dimensional array are electrically coupled together in parallel.

19. The two-dimensional array of light emitting diodes of claim 13, wherein each one-dimensional array comprises a positive contact lead and a negative contact lead on opposite sides of a top side of the substrate.

20. The two-dimensional array of light emitting diodes of claim 13, wherein each one-dimensional array comprises a positive contact lead and a negative contact lead on a same side of a top surface of the substrate.

21. The two-dimensional array of light emitting diodes of claim 20, wherein the substrate of each one-dimensional array further comprises a base, a conductive layer disposed over the base, an insulating layer disposed over the conductive layer, and a plurality of electrically conductive contact regions disposed over the insulating layer; the substrate further comprising a first through via in the insulating layer under one of the positive contact lead and the negative contact lead, and a second through via in the insulating layer under a contact region under a light emitting diode that is on the opposite side of the top surface of the base with respect to the positive contact lead.

22. The two-dimensional array of light emitting diodes of claim 13, wherein the light emitting diodes have a height and wherein there is no component with a height greater than the light emitting diode height that is closer than 2 mm from one of the light emitting diodes.
